(19) United States
(12) Patent Application Publication
(10) Pub. No.: US 2003/0231038 A1
(43) Pub. Date: Dec. 18, 2003

(54) Pulse shaping circuit and method

(76) Inventors: Kenneth Koch II, Ft. Collins, CO (US); John R. Spencer, Ft. Collins, CO (US); Steven L. Jackson, Ft. Collins, CO (US)

Correspondence Address: HEWLETT-PACKARD COMPANY, Intellectual Property Administration, P.O. Box 272400, Fort Collins, CO, 80527-2400, US

(21) Appl. No.: 10/167,494

(22) Filed: Jun. 13, 2002

(51) Int. Cl. H03K 5/12

(52) U.S. Cl. 327/170

(57) ABSTRACT

A pulse shaping circuit includes a series resistor and shunt capacitor that is switched from a finite capacitance value to a substantially open circuit in response to the voltage across the capacitor being on opposite sides of a threshold. The capacitor comprises a MOSFET having a gate connected to the resistor and a source drain path, connected to ground and +Vdd in first and second embodiments, respectively.

### FIELD OF INVENTION

The present invention relates generally to pulse shaping circuits and more particularly to a pulse shaping circuit including a capacitor that is switched between a finite capacitance value and a substantially open circuit during a pulse transition.

### BACKGROUND ART

Pulse shaping circuits frequently employ low pass filters to smooth and/or delay a pulse applied to a load, such as a driver associated with an integrated circuit. It is frequently desirable to slightly delay triggering of such a driver. However, conventional low pass filters including a series resistor and a shunt capacitor have the disadvantage of exponential variations, leading to relatively low slopes as a target voltage is approached. For example, such a low pass filter responds to a positive going voltage transition between 0 and 1.0 Vdd by initially deriving a voltage having a relatively large slope between about 0 and 0.5 Vdd. As time progresses, the derived voltage decreases in slope and theoretically never reaches 1.0 Vdd. For high frequency operation, it is often necessary for the voltage applied to a driver to reach its maximum possible value, such as 1.0 Vdd, as quickly as possible while providing the desired delay. The low slope problem can be particularly acute in high data rate bus applications, where it can lead to inter-symbol interference of a data stream.

In the past, Schmitt triggers have frequently been employed to provide the desired delay, while enabling a voltage applied to a driver to reach its maximum value as quickly as possible. Schmitt triggers, however, are relatively complicated, have trigger voltages which are highly sensitive to (1) integrated circuit chip processing steps, (2) voltages applied to integrated circuit chips including the Schmitt triggers, and (3) temperature variations of the integrated circuit chips. Schmitt triggers frequently cause some form of a crowbar circuit to be activated to override slew rate limiting effects which must be avoided in high frequency applications; the slew rate of a pulse transition is the reciprocal of the pulse transition rise time.

### SUMMARY OF THE INVENTION

One aspect of the invention relates to a method of operating a pulse shaping circuit including a series resistive impedance and a shunt capacitor, wherein the circuit has an input terminal and output terminal, and the shunt capacitor is connected between the output terminal and a reference voltage terminal. The method includes applying a first voltage to the input terminal. Then the voltage applied to the input terminal is changed to provide a transition between the first voltage and a second voltage. Current thus flows through the series resistive impedance and shunt capacitor at a rate determined by the capacitance and resistance values of the shunt capacitor and the resistive impedance. The shunt capacitor is effectively open circuited while current is flowing through it and the resistive impedance. Then, while the transition is still occurring, current is applied between the input and output terminals via the resistive impedance.

Preferably, the shunt capacitor is a voltage controlled capacitor that switches from a finite capacitance value to a substantially open circuit in response to the voltage across the capacitor changing between opposite sides of a voltage threshold between the first and second voltages. Open circuiting of the shunt capacitor is performed in response to the voltage across the capacitor changing from a first side of the voltage threshold to a second side of the voltage threshold.

The shunt capacitor preferably comprises a field effect transistor having a gate electrode, an insulator, and a source drain path. The gate electrode is connected to be responsive to current flowing through the resistive impedance and the source drain path is connected to a power supply terminal.

In accordance with a further aspect of the present invention, a pulse shaping circuit comprises (1) a first terminal responsive to a source having first and second voltage levels and a transition between the levels, (2) a second terminal connected to a reference potential, (3) a voltage controlled switched capacitor having first and second electrodes respectively having DC connections to the first and second terminals, and (4) a resistive impedance. The capacitor has a threshold between the first and second levels such that in response to the voltage across the first and second electrodes being on opposite sides of the threshold the capacitor has a finite capacitance value between the electrodes and a substantially open circuit between the electrodes, respectively. The resistive impedance is connected in circuit with the capacitor so the impedance affects current flow through the capacitor during a portion of the transition while the capacitor has the finite capacitance value. An output terminal is connected to be responsive to the voltage across the electrodes.

Preferably, the resistive impedance is a resistor having a relatively low value that usually cannot be achieved by the source drain impedance of a field effect transistor (FET). The low value of the resistor is desirable for high frequency uses because it provides a relatively short delay time. A resistor also has the advantage over a FET source drain path because the resistive impedance of a resistor is not subject to the extensive variations in value as a function of integrated circuit chip processing, voltage and temperature that accompany a source drain path.

In the preferred embodiment, the resistive impedance is connected for supplying current from the first terminal to the first electrode.

In the preferred embodiment, the capacitor comprises a first field effect transistor including a gate electrode forming the first electrode, a source drain path forming the second electrode, and an insulator between the gate electrode and the source drain path. The threshold is determined by characteristics of the gate electrode, the source drain path and the insulator.

In the preferred embodiments, the first field effect transistor is of a first conductivity type, and a driver forming the load includes a second field effect transistor of a second conductivity type. The second field effect transistor has a gate electrode responsive to the voltage between the gate electrode and the source drain path of the first field effect transistor. The threshold of the first field effect transistor and the connections to the gate electrode and the source drain path thereof are such that current respectively flows and does not flow between the gate and source drain path thereof during initial and final portions of the transition. Such an arrangement helps to provide the desired delay and a fast slew rate.

Another aspect of the invention relates to a pulse shaping circuit comprising first and second opposite conductivity type field effect transistors having gate electrodes connected in a DC circuit to be simultaneously responsive to a variable amplitude voltage at a first terminal. Variations in the voltage at the first terminal are coupled to the gate electrodes of the first and second field effect transistors to affect the capacitances between the gate electrodes and the source drain paths of the first and second field effect transistors. Source drain paths of the first and second field effect transistors are respectively connected to opposite terminals of a DC power supply. The first field effect transistor and the connections to the gate and source drain path thereof are such that in response to the voltage value of the variable amplitude voltage applied to the gate electrode thereof being on opposite sides of a first threshold, a finite capacitance and a substantially open circuit are respectively provided between the first terminal and the source drain path of the first transistor via the gate electrode and insulator of the first field effect transistor. The second field effect transistor and the connections to the gate and source drain path thereof are such that in response to the voltage value of the variable amplitude voltage applied to the gate electrode thereof being on opposite sides of a second threshold a finite capacitance and a substantially open circuit are respectively provided between the first terminal and the source drain path of the second transistor via the gate electrode and the insulator thereof. A resistive impedance arrangement is connected in circuit with the gate electrodes.

Preferably, the resistive impedance arrangement, the first terminal and the gate electrodes and source drain paths of the first and second field effect transistors are such that in response to the source of variable amplitude voltage having a value causing the voltages at the gate electrodes of the first and second field effect transistors to be (1) less than the first threshold, current flows via the resistive impedance arrangement between the gate electrode and source drain path of the first field effect transistor while no current flows between the gate electrode and source drain path of the second field effect transistor, (2) between the first and second thresholds, current flows via the resistive impedance arrangement between the gate electrode and source drain paths of the first and second field effect transistors, and (3) greater than the second threshold, current flows via the resistive impedance arrangement between the gate electrode and source drain path of the second field effect transistor while no current flows between the gate electrode and source drain path of the first field effect transistor. Such an arrangement enables a load to be driven at a high frequency with pulses having very high speed rise and fall times in response to positive and negative going transistors of the voltage source at the first terminal.

The above and still further objects, features and advantages of the present invention will become apparent upon consideration of the following detailed descriptions of several specific embodiments thereof, especially when taken in conjunction with the accompanying drawings.

### BRIEF DESCRIPTION OF THE DRAWING

FIG. 1 is a circuit diagram of a first pulse shaping circuit employing a PFET;

FIG. 2 is a circuit diagram of a second pulse shaping circuit employing an NFET;

FIG. 3 is a circuit diagram of a third pulse shaping circuit employing a PFET and an NFET;

FIG. 4 includes a series of waveforms helpful in describing the operation of the circuits of FIGS. 1-3; and

FIG. 5 is a schematic diagram of a circuit including the pulse shaping circuit of FIG. 1, in combination with an inverter and a driver.

### DETAILED DESCRIPTION OF THE DRAWING

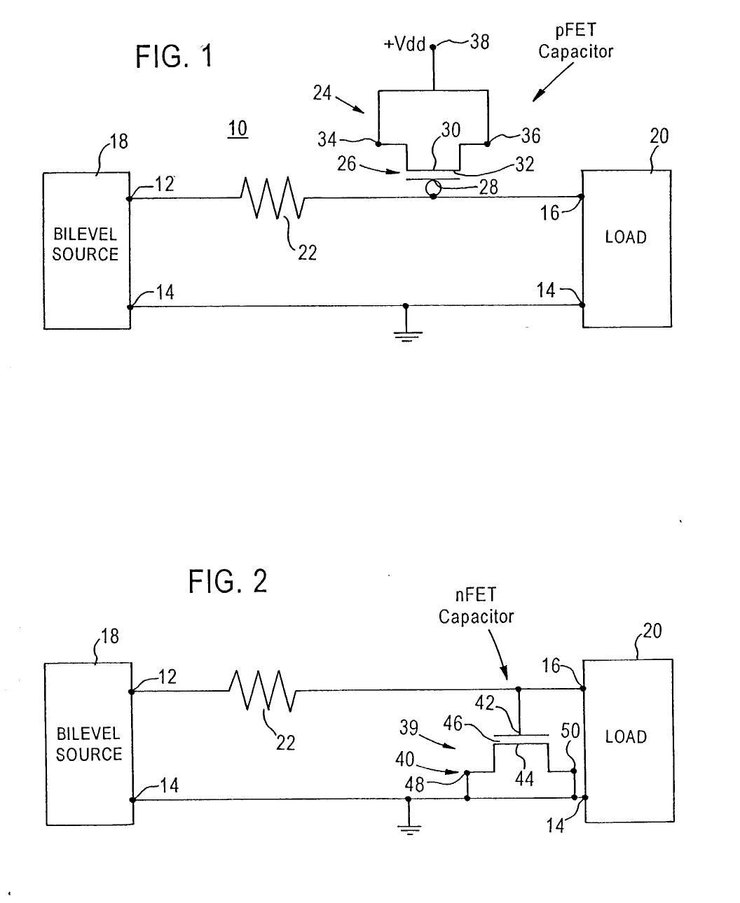

Reference is now made to FIG. 1 of the drawing wherein pulse shaping circuit 10, which is typically included on a complementary metal oxide semiconductor (CMOS) integrated circuit chip, is illustrated as including input and ground terminals 12 and 14, respectively, as well as output terminal 16. Terminals 12 and 14 are connected to output terminals of pulse source 18, which can be a data source or a clock source or any other bilevel source having first and second voltage levels and transitions between the levels. Terminals 16 and 14 are connected to a suitable load 20, such as a driver including one or more field effect transistors (FET) on an integrated circuit.

Pulse shaping circuit 10 is similar to a low pass filter because the pulse shaping circuit includes series resistor 22, connected between terminals 12 and 16, and capacitor 24, connected in shunt between terminals 16 and 14. Capacitor 24 is a voltage controlled, switched capacitor comprising positive channel, i.e., P-type, metal oxide semiconductor field effect transistor (PFET) 26 including gate electrode 28, source drain path 30 and insulator 32 located between electrode 28 and path 30. Electrode 28, which forms one electrode of capacitor 24, is connected in a DC circuit with input terminal 12 by a resistive impedance and in a DC circuit with output terminal 16. The resistive impedance is preferably resistor 22, rather than the source drain path of a field effect transistor (FET) having a constant gate bias voltage. This is because of the considerably lower resistance value which can be achieved with resistor 22 than a FET source drain path. The low resistance value is advantageous because it enables fast rise and fall times to be achieved at terminal 16, while providing a delay at terminal 16 of transitions at terminal 12. In addition, resistor 22 is considerably more stable than a FET source drain port as a function integrated circuit chip (1) processing, (2) DC power supply variations, and (3) temperature.

Source and drain electrodes 34 and 36, at opposite ends of source drain path 30, are connected together to form a second electrode of capacitor 24. Electrodes 34 and 36 have a common connection to the integrated circuit positive DC power supply voltage terminal 38, having a voltage of Vdd. Usually the maximum voltage that source 18 supplies to terminal 12 is Vdd. Ground terminal 14 is connected to ground, i.e., the integrated circuit negative DC power supply voltage terminal, the minimum voltage of source 18.

Gate 28, source drain path 30 and insulator 32 of PFET 26 are such that the PFET has a voltage threshold between ground and Vdd. In response to the voltage between gate electrode 28 and ground 14 being less than the threshold, PFET 26 functions as a conventional capacitor having a finite capacitance between the first electrode formed by gate electrode 28 and the second electrode formed by source drain path 30. In response to the voltage between gate electrode 28 and ground terminal 14 being greater than the threshold, i.e., the voltage across insulator 32 being less than a complementary threshold, the impedance between the first and second electrodes of PFET 26 increases suddenly and substantially so that a substantial open circuit is provided between gate electrode 28 and source drain path 30. Consequently, during an initial portion of a positive going transition of source 18 from the first voltage level (typically at ground), an exponential varying current having a large slope flows between terminal 12 and terminal 38 through capacitor 24 formed by PFET 26. During a subsequent portion of the positive going transition, when the voltage at terminal 12 starts to approach the Vdd voltage at terminal 38 and the slope of the current through capacitor 24 starts to decrease, the threshold of PFET 26 is exceeded in a positive direction. This causes PFET 26 to effectively become an open circuit so that substantial current stops flowing between electrode 28 and source drain path 30. Consequently, the exponential variation suddenly changes and the current flowing through resistor 22 between terminals 12 and 16 increases suddenly and substantially, with an associated sudden increase to +Vdd of the voltage at terminal 16. Since load 20 is typically triggered in response to the voltage level at terminal 16, the triggering level of load 20 occurs earlier in time than if a conventional low pass filter with a conventional capacitor were connected between terminals 12 and 16. In addition, the duration and repetition rate of pulses that source 18 applies to circuit 10 can be shorter than typical low pass filters because the maximum voltage of the transition is much more quickly reached.

Reference is now made to FIG. 2 the drawing which is the same as FIG. 1, except that shunt capacitor 39 is formed of NFET 40, including gate electrode 42, source drain path 44 and insulator 46 between the gate electrode and the source drain path. Source and drain electrodes 48 and 50 at opposite ends of source drain path 44 are connected together and to ground terminal 14, while gate electrode 42 is connected to a common junction of resistor 22 and terminal 16.

Gate electrode 42, source drain path 44 and insulator 46 of NFET 40 are such that the NFET has a voltage threshold between ground and Vdd. In response to the voltage between gate electrode 42 and ground 14 being greater than the threshold, NFET 40 functions as a conventional capacitor having a finite capacitance value between the first electrode formed by gate electrode 42 and the second electrode formed by source drain path 44. In response to the voltage between gate electrode 42 and ground terminal 14 being less than the threshold, the impedance between the first and second electrodes of NFET 40 increases suddenly and substantially so that a substantial open circuit is provided between gate electrode 42 and source drain path 44. Consequently, during an initial portion of a negative going transition of source 18 from the second voltage level (typically at Vdd) an exponential varying current having a large slope flows between terminal 12 and ground terminal 14 through capacitor 39 formed by NFET 40. During a subsequent portion of the negative going transition, when the voltage at terminal 12 starts to approach the ground voltage at terminal 14 and the slope of the current through capacitor 39 decreases, the threshold of NFET 40 is exceeded in a negative direction. This causes NFET 40 to effectively become an open circuit, so that substantial current stops flowing between electrode 42 and source drain path 44. Consequently, the exponential variation suddenly changes and the current flowing between terminals 12 and 16 decreases suddenly and substantially, with an associated sudden decrease to zero volts at terminal 16.

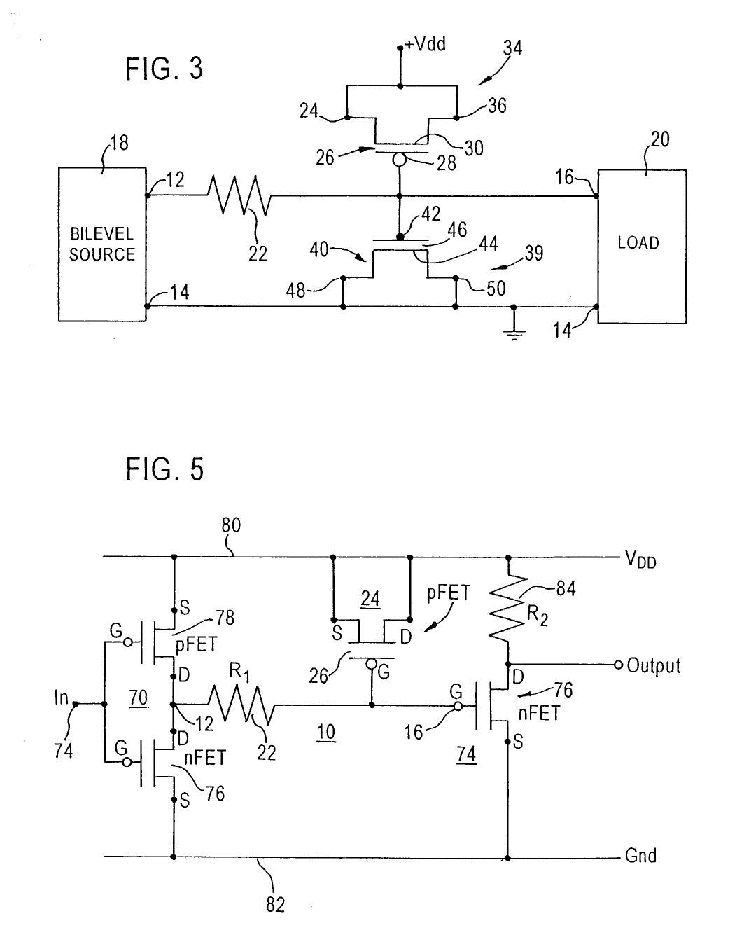

Reference is now made to FIG. 3 of the drawing wherein the circuits of FIGS. 1 and 2 are combined so that gate electrode 28 of PFET 26 and gate electrode 42 of NFET 40 are connected to a common junction of terminal 16 and resistor 22. In the circuit of FIG. 3, the threshold of PFET 26 is greater than the threshold of NFET 40. For voltages of source 18 less than the threshold of NFET 40, exponential current having a relatively large slope flows through resistor 22 and the capacitor 24 formed by PFET 26. For voltages of source 18 greater than the threshold of PFET 26, exponential current having a relatively large slope flows through resistor 22 and capacitor 39 formed by NFET 40. For voltages of source 18 between the threshold of PFET 26 and NFET 40 exponential current having an intermediate slope flows through both capacitors 26 and 39, resulting in a substantial increase in current through resistor 22 relative to the current that flows through the resistor for voltages exceeding the threshold of PFET 26 and less than the threshold of NFET 40.

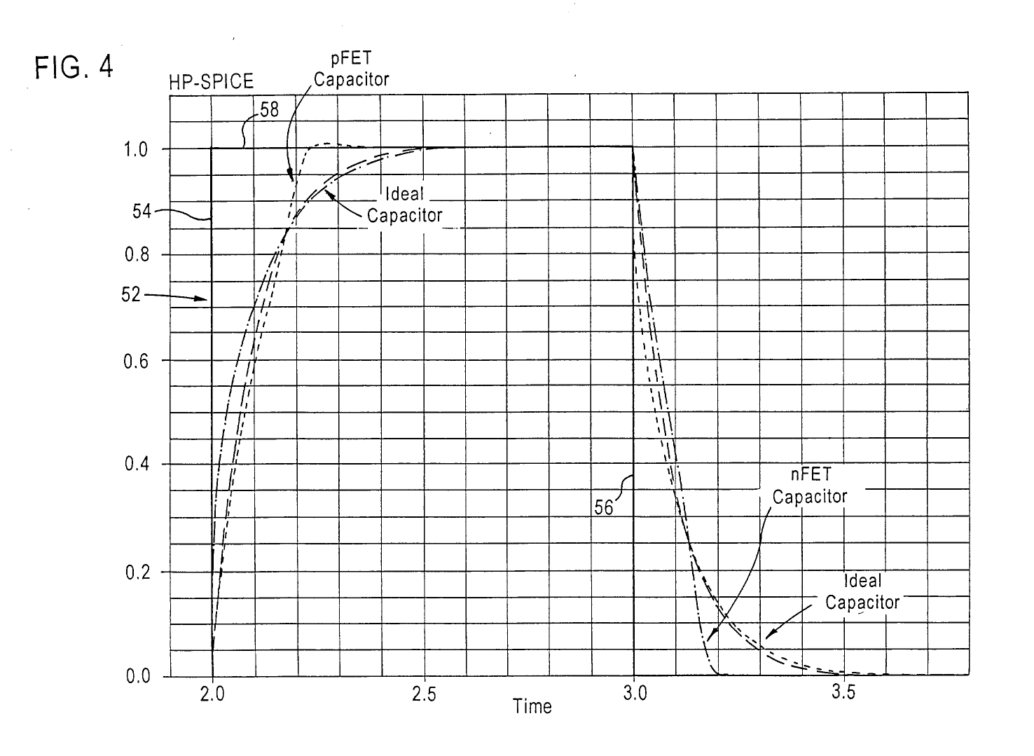

Reference is now made to FIG. 4 the drawing wherein the square wave output of source 18 is indicated by waveform 52, assumed to have positive and negative going transitions 54 and 56, respectively, between 0 V and 1.0 Vdd, as well as a constant value at 1.0 Vdd for a predetermined interval, such as one picosecond. Waveform 58 (a series of short dashes) indicates the voltage across terminals 14 and 16 in the circuit of FIG. 1 in response to waveform 52. Waveform 60 (a series of dots and dashes) indicates the voltage across terminals 14 and 16 in the circuit of FIG. 2 in response to waveform 52. Waveform 62 (a series of long dashes) indicates the voltage that would have been across terminals 14 and 16 in the circuits of FIGS. 1 and 2 in response to waveform 52, if PFET 26 and NFET 40 were replaced by conventional capacitors.

The thresholds of PFET 26 and NFET 40 are respectively indicated in FIG. 4 at 0.84 Vdd and 0.25 Vdd. For voltages between 0 and the 0.84 Vdd threshold of PFET 26, waveforms 58 and 62 track each other substantially. Above the 0.84 Vdd threshold, the slope of waveform 58 is substantially greater than the slope of waveform 62 as result of the impedance between gate electrode 28 and source drain path 30 increasing substantially in response to the threshold of PFET 26 being exceeded. For voltages between Vdd and the 0.25 Vdd threshold of NFET 40, waveforms 60 and 62 track each other substantially. Below the 0.25 Vdd threshold, the slope of waveform 60 is substantially greater than the slope of waveform 62 as result of the impedance between gate electrode 42 and source drain path 44 increasing substantially in response to the threshold of NFET 40 being crossed in a negative direction. Consequently, waveforms 58 and 60 reach the target values of 1.0 Vdd and OV considerably sooner than waveform 62.

Reference is now made to FIG. 5 the drawing wherein pulse shaping circuit 10, illustrated in FIG. 1, is incorporated in an integrated circuit chip including inverter 70 and off-chip driver 72, that functions as a pull down stage.

Inverter 70 includes input terminal 74 connected to be responsive to a bilevel input voltage such as associated with a data signal or a clock source. Inverter 70 includes NFET 76 and PFET 78 having gate electrodes tied to4 terminal 74 and series connected source drain paths between the integrated circuit chip positive DC power supply terminal 80 and ground terminal 82. The drains of NFET 76 and PFET 78 are tied together, to provide input terminal 12 of FIG. 1.

Driver 74 includes NFET 76 having a gate electrode that can be considered as forming terminal 16, FIG. 1. NFET 76 has a source drain path such that the source of the NFET is connected to ground terminal 82 and the drain of the NFET is connected to DC power supply terminal 80 through resistor 84. The output of driver 74 is between the drain of NFET 76 and ground. Pulse shaping circuit 10, including series resistor 22 and voltage controlled switched shunt capacitor 24 comprising PFET 26, is connected between inverter 70 and driver 74. NFET 76 has a threshold less than the threshold of PFET 26 so that NFET 76 is on while the output voltage of inverter 74 is increasing rapidly from 0V to the NFET threshold (about 0.4 Vdd) and is off while the output voltage of the inverter increases from 0.4 Vdd to 1.0 Vdd. The 1.0 Vdd target voltage is reached rapidly as a result of capacitor 24 being switched off in response to the threshold of PFET 26 being crossed when the inverter output exceeds about 0.7 Vdd.

Pulse shaping circuit 10 functions as a slew-rate control element for integrated circuit off-chip driver 72. Inverter 70 and driver 72 are sized (i.e., the widths of the insulators between the gate electrodes and the source drain paths thereof) such that delays through each of the inverter and driver are small with respect to the time constant of the low pass filter formed by pulse shaping circuit 10.

The total delay of the circuit of FIG. 5 is thus dominated by the resistance capacitance (RC) time constant of resistor 22 and capacitor 24 during the interval while the voltage across capacitor 24 is less than the threshold of the capacitor. Because PFET 26 is a P-channel metal oxide semiconductor field effect transistor (MOSFET) with a source drain path connected to Vdd and a gate electrode connected to the gate electrode of the n-channel pull-down FET 76, the rise-time (reciprocal of slew rate) at the drain of NFET 76 is limited by the resistance capacitance (RC) time constant of resistor 22 and capacitor 24 for voltages at terminal 12 less than the threshold of PFET 26. In certain instances, this is advantageous because the low pass filtering or delay characteristics of circuit 10 prevent premature firing of driver 72. In response to the voltage at terminal 12 exceeding the threshold of PFET 26, the voltage at terminal 16 quickly rises to Vdd. In certain instances this is advantageous, because it enables the frequency of data or clock pulses applied to terminal 74 to be increased because the need to complete the relatively slow exponential variations (which occur as the exponential voltage approaches Vdd) normally associated with a low pass filter is avoided.

While there have been described and illustrated specific embodiments of the invention, it will be clear that variations in the details of the embodiments specifically illustrated and described may be made without departing from the true spirit and scope of the invention as defined in the appended claims.

We claim:

1. A method of operating a pulse shaping circuit including a series resistive impedance and a shunt capacitor, the circuit having input and output terminals, the capacitor being connected between the output terminal and a reference voltage terminal, comprising the steps of applying a first voltage to the input terminal, then changing the voltage supplied to the input terminal so there is a transition to a second voltage, during an initial portion of the transition causing current to flow through the resistive impedance and capacitor at a rate determined by the capacitance and resistance values of the capacitor and resistive impedance, and during a subsequent portion of the transition effectively open circuiting the capacitor while current is flowing through the capacitor, and during the remainder of the transition causing current to flow between the terminals via the resistive impedance, while the capacitor is effectively open circuited.

2. The method of claim 1 wherein the shunt capacitor is a voltage controlled capacitor that switches from a finite capacitance value to a substantially open circuit in response to the voltage across the capacitor changing between opposite sides of a voltage threshold, open circuiting of the shunt capacitor being performed by the shunt capacitor responding to the voltage across the capacitor changing from a first side of the voltage threshold to a second side of the voltage threshold.

3. The method of claim 2 wherein the shunt capacitor comprises a gate electrode of a field effect transistor, an insulator of the field effect transistor, and a source drain path of the field effect transistor, the method further comprising connecting the gate electrode to be responsive to current flowing through the resistive impedance, and connecting the source drain path of the field effect transistor to a power supply terminal.

4. A pulse shaping circuit comprising a first terminal adapted to be responsive to a source having first and second voltage levels and a transition between the levels; a second terminal connected to a reference potential; a voltage controlled switched capacitor having first and second electrodes respectively having DC connections to the first and second terminals, the capacitor having a threshold between the first and second levels such that in response to the voltage across the first and second electrodes being on opposite sides of the threshold the capacitor respectively has, between the electrodes, a finite capacitance value and a substantially open circuit; a resistive impedance connected in circuit with the capacitor for affecting current flow through the capacitor during a portion of the transition while the capacitor has the finite capacitance value; and an output terminal connected to be responsive to the voltage across the electrodes.

5. The circuit of claim 4 wherein the resistive impedance is connected in the circuit for supplying current from the first terminal to the first electrode.

6. The circuit of claim 5 further including a load comprising a driver, the driver being connected to be responsive to the voltage at the output terminal.

7. The circuit of claim 6 further including the source, wherein the source includes an inverter.

8. The circuit of claim 6 wherein the capacitor comprises a first field effect transistor, the first field effect transistor including a gate electrode forming the first electrode, a source drain path forming the second electrode, and an insulator between the gate electrode and the source drain path, the threshold being determined by characteristics of the gate electrode, the source drain path and the insulator.

9. The circuit of claim 8 wherein the first field effect transistor is of a first conductivity type, and the driver includes a second field effect transistor of a second conductivity type and having a gate electrode connected to be responsive to the voltage between the gate electrode and the source drain path of the first field effect transistor.

10. The circuit of claim 9 wherein the threshold of the first field effect transistor and the connections to the gate electrode and the source drain path thereof are such that current respectively flows and does not flow between the gate and source drain path thereof during initial and final portions of the transition.

11. The circuit of claim 10 wherein the first and second field effect transistors are respectively P type and N type, the source drain path of the first field effect transistor being connected to a positive DC power supply terminal, the second field effect transistor including source and drain electrodes respectively connected in circuit with negative and positive DC power supply terminals.

12. The circuit of claim 4 wherein the pulse shaping circuit is included on an integrated circuit chip and the resistive impedance includes a resistor on the integrated circuit chip.

13. The circuit of claim 4 wherein the capacitor comprises a first field effect transistor, the first field effect transistor including a gate electrode forming the first electrode, a source drain path forming the second electrode, and an insulator between the gate electrode and the source drain path, the threshold being determined by characteristics of the gate electrode, the source drain path and the insulator.

14. The circuit of claim 13 wherein the first field effect transistor is P type, the source drain path of the first field effect transistor being connected to a positive DC power supply terminal.

15. The circuit of claim 14 wherein the resistive impedance is connected for supplying current from the first terminal to the gate electrode.

16. The circuit of claim 13 wherein the first field effect transistor is N type, the source drain path of the first field effect transistor being connected to a negative DC power supply terminal.

17. The circuit of claim 16 wherein the resistive impedance is connected for supplying current from the first terminal to the gate electrode.

18. A pulse shaping circuit comprising a first terminal for connection to a source of variable amplitude voltage; first and second field effect transistors of opposite conductivity type, each of the field effect transistors having (a) a source drain path, (b) a gate electrode, and (c) an insulator between the gate electrode and the path, the source drain paths of the first and second field effect transistors being respectively connected to a terminal adapted to be connected to opposite DC power supply terminals; the gate electrodes of the first and second field effect transistors being connected in a DC circuit to be simultaneously responsive to the voltage at the first terminal so that variations in the voltage at the first terminal are coupled to the gate electrodes of the first and second field effect transistors to affect the capacitances between the gate electrodes and the source drain paths of the first and second field effect transistors; the first field effect transistor and the connections to the gate and source drain path thereof being such that in response to the voltage value of the variable amplitude voltage applied to the gate electrode thereof being respectively on opposite sides of a first threshold, a finite capacitance and a substantially open circuit are provided between the first terminal and the source drain path of the first transistor via the gate electrode and the insulator thereof; the second field effect transistor and the connections to the gate and source drain path thereof being such that in response to the voltage value of the variable amplitude voltage applied to the gate electrode thereof being respectively on opposite sides of a second threshold, a finite capacitance and a substantially open circuit are provided between the first terminal and the source drain path of the second transistor via the gate electrode and the insulator thereof; and a resistive impedance arrangement connected in circuit with the gate electrodes.

19. The circuit of claim 18 wherein the resistive impedance arrangement is connected for supplying current responsive to the voltage at the first terminal to the gate electrodes of the first and second field effect transistors.

20. The circuit of claim 19 wherein the resistive impedance arrangement, the first terminal and the gate electrodes and source drain paths of the first and second field effect transistors are such that in response to the source of variable amplitude voltage having a value causing the voltage at the gate electrodes of the first and second field effect transistors to be: (a) less than the first threshold, current flows via the resistive impedance arrangement between the gate electrode and source drain path of the first field effect transistor while no current flows between the gate electrode and source drain path of the second field effect transistor, (b) between the first and second thresholds, current flows via the resistive impedance arrangement through the gate electrodes and source drain paths of the first and second field effect transistors, and (c) greater than the second threshold, current flows via the resistive impedance arrangement between the gate electrode and source drain path of the second field effect transistor while no current flows between the gate electrode and source drain path of the first field effect transistor.

21. The circuit of claim 20 wherein the pulse shaping circuit is included on an integrated circuit chip and the resistive impedance arrangement includes a resistor on the integrated circuit chip.
